(19) United States
(12) Patent Application Publication
(10) Pub. No.: US 2009/0195293 A1
(43) Pub. Date: Aug. 6, 2009

(54) EMITTER-SWITCHED BIPOLAR TRANSISTOR

(75) Inventor: Hans Oppermann, Bad Vilbel (DE)

Correspondence Address: HOVEY WILLIAMS LLP, 10801 Mastin Blvd., Suite 1000, Overland Park, KS, 66210, US

(73) Assignee: CONERGY AG, Hamburg (DE)

(21) Appl. No.: 12/159,558

(22) PCT Filed: Dec. 28, 2006
(86) PCT No.: PCT/EP06/12573

§ 371 Date: Nov. 19, 2008

(30) Foreign Application Priority Data
Dec. 28, 2005 (DE) 10 2005 062 755.2

(51) Int. Cl. H03K 17/567

(52) U.S. Cl. 327/374

(57) ABSTRACT

The invention relates to a power circuit with a emitter-switched bipolar transistor (ESBT) (T2) and a MOS transistor (T3) connected downstream of the bipolar transistor. The bipolar transistor (T2) is controlled by a Mosfet transistor (T1). A zener diode (D1) which is disposed between the exit of the MOS transistor (T3) and the base of the bipolar transistor (T2) transmits the return current of the base collector diode of the bipolar transistor (T2) to the foot point of the ESBT (T2). Furthermore, a voltage source (U) is inserted between the collector of the bipolar transistor (T2) and the drain of the Mosfet transistor (T1).

The invention relates to a circuit in accordance with the preamble of patent claims 1 or 4.

In inverters, frequency converters, power supplies and other power applications, IGBTs (Insulated Gate Bipolar Transistors) are predominantly employed. In this case, large currents are often switched at high operating voltages. An undesirable reduction of efficiency occurs here as a result of slow switching edges and high saturation voltages and also current tail losses which can be attributed to the fact that the subsiding load current and the full operating voltage are present in part simultaneously.

Besides IGBTs, attempts have also already been made to work with ESBT configurations. “ESBT” here stands for “emitter-switched bipolar transistor”. In this case, a MOS transistor is connected downstream of the NPN power transistor and has the task of interrupting the emitter current of the bipolar transistor if the load is intended to be switched off. This has the effect that the load current is then forwarded via the collector-base diode until the space charge zone has built up again between base and collector and the transistor has regained its normal blocking capability. However, ESBTs have the disadvantage over IGBTs that they require a comparatively large base current.

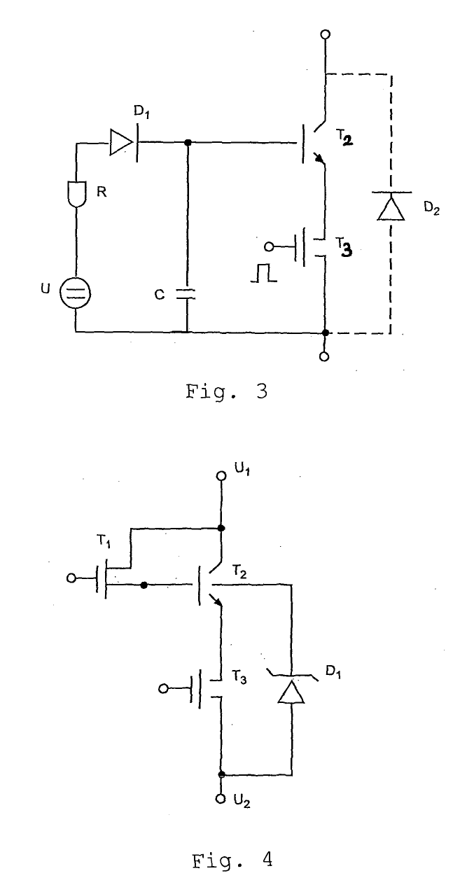

ST_Microsystems has furthermore disclosed a further-developed ESBT circuit for lower powers (in the range of 1-2 kW), in which a storage capacitor for overcoming the switch-on inertia supplies a current surge via a base-emitter diode of the NPN transistor and thus drives the NPN transistor into saturation. Only after a delay time associated with the depletion of the charge carriers from the base zone is it possible to switch the ESBT off again. However, this may be too late in the event of a short circuit (FIG. 3).

U.S. Pat. No. 4,547,686 A discloses a power circuit comprising an emitter-controlled bipolar transistor (Q1) with a MOS transistor (Q3) connected downstream thereof, wherein the bipolar transistor (Q1) is driven by a MOSFET transistor (Q2). One disadvantage of this circuit is that it can only switch into unsaturated operation.

A similar circuit having the same disadvantages is disclosed by DE 38 39 156 A1.

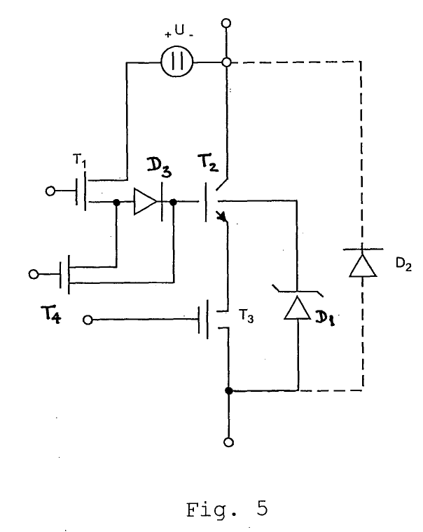

EP 0 190 931 B1 discloses, in FIG. 5, an ESBT with MOS driver in accordance with the preamble of claim 1 and furthermore also has a freewheeling diode 5 in antiparallel with the ESBT. A parallel backward current via the base-collector junction of the ESBT is nevertheless not ruled out since a further diode 8 is provided, which does not have a limiting effect on both sides. This citation, too, can only switch the ESBT into unsaturated operation.

ESBTs have been known for more than 20 years but, despite the good switching properties, have been unable to gain acceptance owing to the high drive currents. A further deficiency is that ESBTs cannot be used in half- and full-bridges nor in three-phase topologies since reverse currents can interfere with or destroy these.

It is an object of the invention to overcome these deficiencies mentioned above.

An altered ESBT circuit having the features of patent claim 1 or, complementarily thereto, the features of patent claim 4 serves for achieving said object.

The subclaims relate to advantageous configurations of the invention.

The invention is explained in more detail below with reference to a drawing, in which:

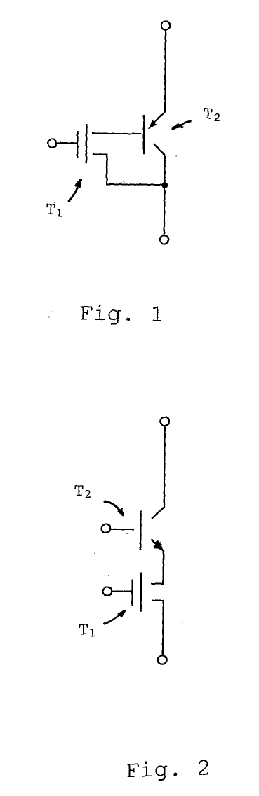

FIG. 1 shows a known IGBT circuit;

FIG. 2 shows a known ESBT circuit;

FIG. 3 shows a further known ESBT circuit;

FIG. 4 shows a first embodiment of an ESBT circuit improved according to the invention;

FIG. 5 shows a second embodiment of the invention;

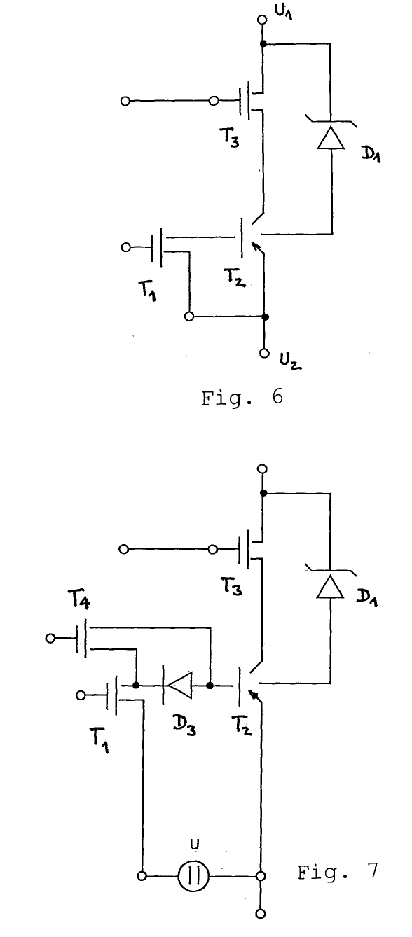

FIG. 6 shows a modification of the first embodiment according to FIG. 4; and

FIG. 7 shows a modification of the second embodiment according to FIG. 5.

In the figures identical parts are illustrated and designated with identical reference symbols.

FIG. 1 shows the functional circuit diagram of a known IGBT. A driver MOSFET T₁ can be seen, followed by a PNP transistor T₂. Upon switch-on, the driver MOSFET T₁ initially determines the switching speed for the load current. The downstream PNP transistor T₂ switches in with a delay. The delay results from the fact that the base region first has to be flooded with charge carriers until the base-collector space charge zone has been reduced and the PNP transistor T₂ has become conductive. This again reduces the saturation voltage of the IGBT. Upon switch-off, the MOSFET T₁ reacts very rapidly. However, the PNP transistor T₂ follows the switch-off only when the charge carriers have been extracted again from the base region by the load current. This subsiding of the collector current is also referred to as “current tail”. Precisely in the case of high-current IGBTs with hundreds of amperes, this circumstance considerably limits the limiting frequency of the semiconductor since in part subsiding load current and full operating voltage are present simultaneously.

FIG. 2 shows a known ESBT circuit wherein a MOS transistor T₃ is connected downstream of the NPN power transistor T₂, said MOS transistor having the task of interrupting the emitter current from the NPN power transistor T₂ if the load is intended to be switched off. This has the effect that the load current is then forwarded via the collector-base diode until the space charge zone has built up again between base and collector and the transistor has regained its normal blocking capability. However, ESBTs have the disadvantage over IGBTs that they require a comparatively large base current.

FIG. 3 shows an ESBT circuit for lower powers of 1-2 kW developed by ST_Microsystems. The drawing makes it clear that, in addition to switching on the emitter of MOS transistor T₃, the base of the NPN transistor T₂ has to be driven with a current of ⅕ I_{c} in order to achieve a sufficiently low saturation voltage Uceₛₐₜ. This would then be a base current of 6 A in the case of a 30 A ESBT and it shows the great disadvantage compared with the IGBT with regard to the drive power. Furthermore, a problem also arises when the ESBT is switched on. In order to overcome the switch-on inertia, a current surge is drawn from the storage capacitor C via a base-emitter diode T₂ and drives the T₂ into saturation. Only after a delay time associated with the depletion of the charge carriers from the base zone is it possible to switch the ESBT off again. However, this may be too late in the event of a short circuit.

### Solution of the Problems of ESBT Configurations:

FIG. 4 shows an altered ESBT configuration. In this case, the driver MOSFET T₁ and the emitter switch T₃ switch the entire load current via the base-emitter diode from the NPN transistor T₂. Although this leads to the fast switching-on of the load current, a low saturation voltage is established only when the NPN transistor T₂ has reduced the space charge zone of the base-collector diode by means of the base current. Upon switch-off of the ESBT, firstly T₁ and T₃ are turned off again. The collector-base backward current then established is passed on via the bidirectional limiter diode (transzorb diode) D₁ and the voltage at the base of T₂ is limited to an optimum extent in order also to obtain voltage protection for T₃ and in order to prevent a reverse current from the load circuit via the base-collector diode T₂. After a time t_{d}, T₂ then switches off with a very steep current and voltage edge.

FIG. 5 shows a further configuration of the ESBT such that, in series with the driver MOSFET T₁, a voltage source U is connected between the collector of T₂ and the drain of T₁. The voltage source U helps to be able to control the transistor T₂ from quasi-saturation to a very low saturation voltage. The diode D₃ in series with the source terminal of T₁ is used as a counter-voltage source with respect to U in order also to be able to drive T₂ into quasi-saturation.

Upon switch-on, the switch T4 will initially remain open until T₂ has switched in, i.e. is in quasi-saturation. Afterward, the diode D3 is bridged by the switch T₄ and T₂ can be driven down to a very low saturation voltage.

Upon switch-off, firstly only the switch T4 is opened and the transistor T₂ is driven back to quasi-saturation. Afterward, T₁ also opens and T₄ and T₂ switch off very rapidly.

Further ESBT variants arise if the bipolar transistor T₂ is a PNP transistor.

FIG. 6 shows a correspondingly analogous configuration of the circuit from FIG. 4, wherein the transistor T2 is a PNP transistor.

FIG. 7 shows an analogous configuration of the circuit from FIG. 5, in which the bipolar transistor T2 is likewise once again a PNP transistor.

1. A power circuit comprising:
an emitter-controlled bipolar transistor with a MOS transistor connected downstream thereof;
a MOSFET transistor driving the bipolar transistor;
a limiter diode lying between an output of the MOS transistor and a base of the bipolar transistor, which diode forwards the reverse current of a base-collector diode of the bipolar transistor to a reference point of the ESBT; and
a voltage source between a collector of the bipolar transistor and a drain of the MOSFET transistor.

2. The power circuit as claimed in claim 1,
said limiter diode being a symmetrical limiter diode with blocking capability in two directions, such that a backward current via the base-collector diode of the bipolar transistor is thus prevented.

3. The power circuit as claimed in claim 1,
said driver MOSFET being followed by a diode at the source, and said diode being bridgeable by a parallel MOSFET,
said parallel MOSFET remaining open upon switch-on in order that the bipolar transistor, for a reliable mode of operation, firstly only attains the quasi-saturated state, while it is only afterward that the parallel MOSFET bridges the diode and the bipolar transistor is driven into saturation,
said parallel MOSFET being opened again upon switch-off such that the bipolar transistor is led into quasi-saturated operation in order then to be able to be switched off rapidly and with few losses by means of the driver MOSFET and MOS transistor.

4. A power circuit comprising:
an emitter-controlled bipolar transistor with a MOS transistor connected upstream thereof;
a MOSFET transistor driving the bipolar transistor;
a limiter diode lying between an input of the MOS transistor and a base of the bipolar transistor, which diode forwards the reverse current of a base-collector diode of the bipolar transistor to a reference point of the ESBT; and
a voltage source between an emitter of the bipolar transistor and a drain of the MOSFET transistor.

5. The power circuit as claimed in claim 4,
said limiter diode being a symmetrical limiter diode with blocking capability in two directions, such that a backward current via the base-collector diode of the bipolar transistor is thus prevented.

6. The power circuit as claimed in claim 4, said driver MOSFET being followed by a diode at the source, and said diode being bridgeable by a parallel MOSFET,
said parallel MOSFET remaining open upon switch-on in order that the bipolar transistor, for a mode of operation, firstly only attains the quasi-saturated state, while it is only afterward that the parallel MOSFET bridges the diode and the bipolar transistor is driven into saturation,
said parallel MOSFET being opened again upon switch-off such that the bipolar transistor is led into quasi-saturated operation in order then to be able to be switched off rapidly and with few losses by means of the driver MOSFET and MOS transistor.
